(19) United States
(12) Patent Application Publication
(10) Pub. No.: US 2014/0042123 A1
(43) Pub. Date: Feb. 13, 2014

(54) PLASMA PROCESSING APPARATUS AND PLASMA PROCESSING METHOD

(71) Applicant: Masaki Hirayama, Sendai-shi (JP)

(72) Inventor: Masaki Hirayama, Sendai-shi (JP)

(73) Assignee: TOHOKU UNIVERSITY, Sendai-shi, Miyagi (JP)

(21) Appl. No.: 14/113,825

(22) PCT Filed: Feb. 23, 2012
(86) PCT No.: PCT/JP2012/001252

§ 371 Date: Oct. 25, 2013

(51) Int. Cl. H01J 37/04

(52) U.S. Cl. CPC H01J 37/04
USPC 216/67; 156/345.43; 156/345.34

(57) ABSTRACT

A plasma processing apparatus which can improve density uniformity of plasma excited by a high frequency wave (such as in the VHF frequency band) for a substrate having a large size. The plasma processing apparatus includes a waveguide member defining a waveguide, a coaxial tube supplying electromagnetic energy from a predetermined power supply position in the longitudinal direction of the waveguide into the waveguide, and a plurality of electrodes for electric field formation, to which the electromagnetic energy is supplied through the waveguide and which is disposed so as to face a plasma formation space, the plurality of electrodes are being arranged in the longitudinal direction of the waveguide, and each of the plurality of electrodes extends in the width direction of the waveguide.

### TECHNICAL FIELD

The present invention relates to a plasma processing apparatus and a plasma, processing method which apply plasma processing to a substrate.

### BACKGROUND ART

In the manufacturing processes of a flat-plate display, a solar battery, a semiconductor device, and the like, plasma is used for thin film formation, etching, and the like. For example, plasma is generated by means of introducing gas into a vacuum chamber and applying a high frequency wave of several MHz to several hundred MHz to an electrode provided in the chamber. For improving productivity, a glass-substrate size of the flat-plate display or the solar battery is increased year by year and already volume production is being carried out using a glass substrate having a size exceeding 2 m square.

In a film deposition process such as plasma CVD (Chemical Vapor Deposition), plasma having a higher density is required for improving a film deposition rate. Further, plasma having a lover electron temperature is required for suppressing the energy of an ion entering a substrate surface to reduce ion irradiation damage and also for suppressing excessive disassociation of a gas molecular. Generally, when a plasma excitation frequency is increased, the plasma density is increased and the electron temperature is reduced. Accordingly, for depositing a high quality thin film at a high throughput, it is necessary to increase the plasma excitation frequency. Therefore, it has been tried to use a high frequency wave in the VHF (Very High Frequency) band of 30 to 300 MHz, which is higher than 13.56 MHz of a frequency for a typical high-frequency power source, for the plasma processing (refer to Patent Literatures 1 and 2, for example).

### CITATION LIST

### Patent Literature

PTL 1: Japanese Patent Laid-Open No. H09-312268 (1997)

PTL 2: Japanese Patent Laid-Open No. 2009-021256

### SUMMARY OF THE INVENTION

### Technical Problem

Meanwhile, when a glass substrate to be processed has a large size such as 2 m square, for example, and is plasma-processed, at a plasma excitation frequency of the VHF band as described above, uniformity of the plasma density is degraded because of a standing wave of a surface wave caused in an electrode to which the high frequency wave is applied. Generally, when the electrode to which the high frequency wave la applied has a size larger than 1/20 of a free space wavelength, it is difficult to excite uniform plasma without any countermeasure.

The present invention provides plasma processing apparatus which can improve the density uniformity of the plasma excited by a high frequency wave as in the VHF frequency band, for a substrate having a large size exceeding 2 m square.

### Solution to Problem

A plasma processing apparatus of the present invention includes a waveguide member defining a ware guide, a transmission path supplying electromagnetic energy from a predetermined power supply position in a longitudinal direction of the waveguide rate the waveguide; and a plurality of electrodes for electric field formation, to which the electromagnetic energy is supplied through the waveguide and which is disposed so as to face a plasma formation space, wherein the plurality of electrodes is arranged along the longitudinal direction of the waveguide, and each of the plurality of electrodes extends in a width direction of the waveguide.

### Advantageous Effects of Invention

According to the present invention, it is possible to improve density uniformity of plasma excited in the VHF frequency band in the longitudinal direction and the width direction of the waveguide, for a larger object (substrate) to be processed.

### BRIEF DESCRIPTION OF DRAWINGS

FIG. 1 is a cross-sectional view showing an example of a plasma processing apparatus;

FIG. 2 is a II-II cross-sectional view of the plasma processing apparatus of FIG. 1;

FIG. 3A is a perspective cross-sectional view showing a waveguide tube in a cut-off state;

FIG. 3B is a perspective cross-sectional view of a waveguide having an equivalent relationship with the waveguide tube of FIG. 3A;

FIG. 4 is a perspective cross-sectional view showing a structure of a basic-type plasma generation mechanism in the plasma processing apparatus of FIG. 1;

FIG. 5 is a perspective cross-sectional view showing a structure of a plasma generation mechanism according to a first embodiment of the present invention;

FIG. 6 is a perspective cross-sectional view showing an external appearance viewed from a coaxial tube side of the plasma generation mechanism of FIG. 5;

FIG. 7 is a perspective cross-sectional view showing an external appearance viewed from an electrode side of the plasma generation mechanism of FIG. 5;

FIG. 8 is a perspective view of an electrode unit;

FIG. 9 is a cross-sectional view of the electrode unit;

FIG. 10 is a diagram for explaining electric field formation in the electrode unit;

FIG. 11 is a perspective view showing another example of an electrode unit;

FIG. 12 is a cross-sectional view of the electrode unit of FIG. 11; and

FIG. 13 is a graph showing an example of an electric field strength distribution in the width direction of a waveguide in a basic-type plasma generation mechanism.

### DESCRIPTION OF EMBODIMENTS

Hereinafter, an embodiment of the present invention will be explained in detail with reference to the attached drawings, Note that, in the present specification and the drawings, the same sign is provided for a constituent having substantially the same functional configuration and repeated explanation will be omitted.

### [Basic Configuration of a Plasma Processing Apparatus]

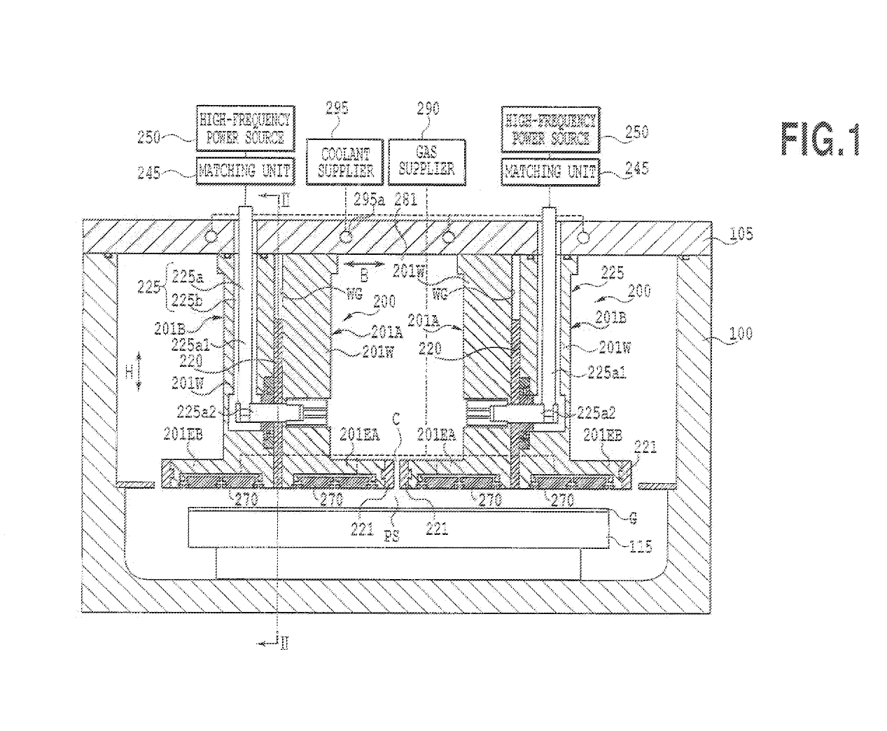

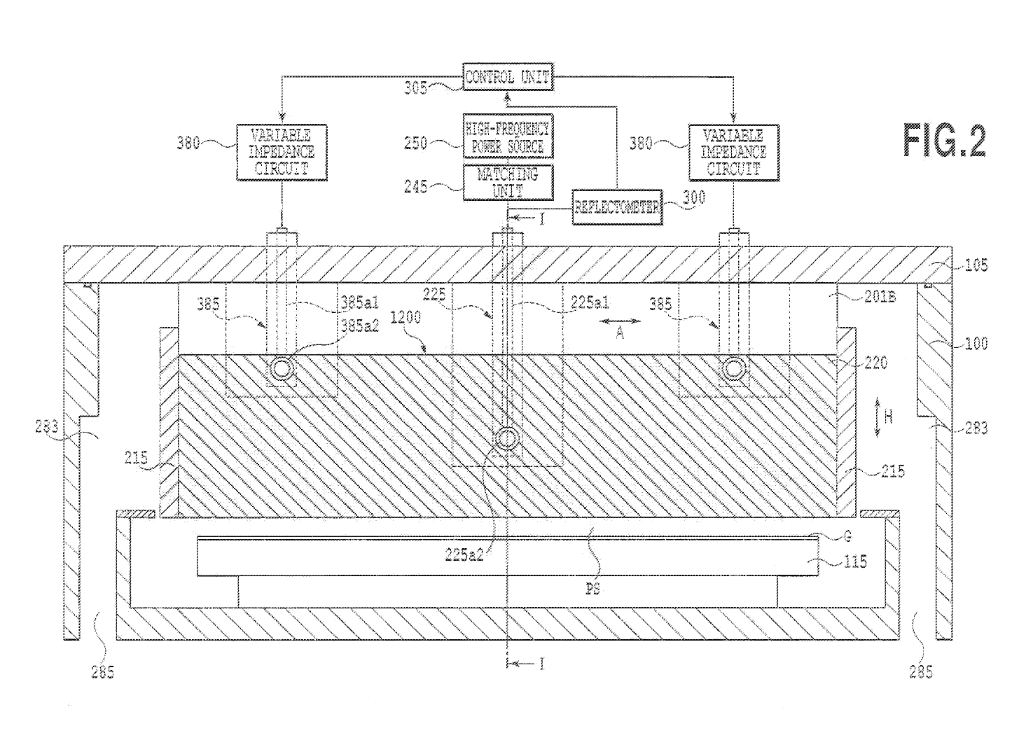

First, an example of a plasma processing apparatus of a type to which the present invention is applied will be explained with reference to FIG. 1 and FIG. 2. FIG. 1 is a I-I cross-sectional view of FIG. 2, and FIG. 2 is a II-II cross-sectional view of FIG. 1. A plasma processing apparatus 10 shown in FIG. 1 and FIG. 2 has a configuration in which electromagnetic energy is supplied to an electrode by the use of a waveguide which is designed so as to cause a supplied electromagnetic wave to resonate and thereby plasma having uniform density along the longitudinal direction of the waveguide can be excited.

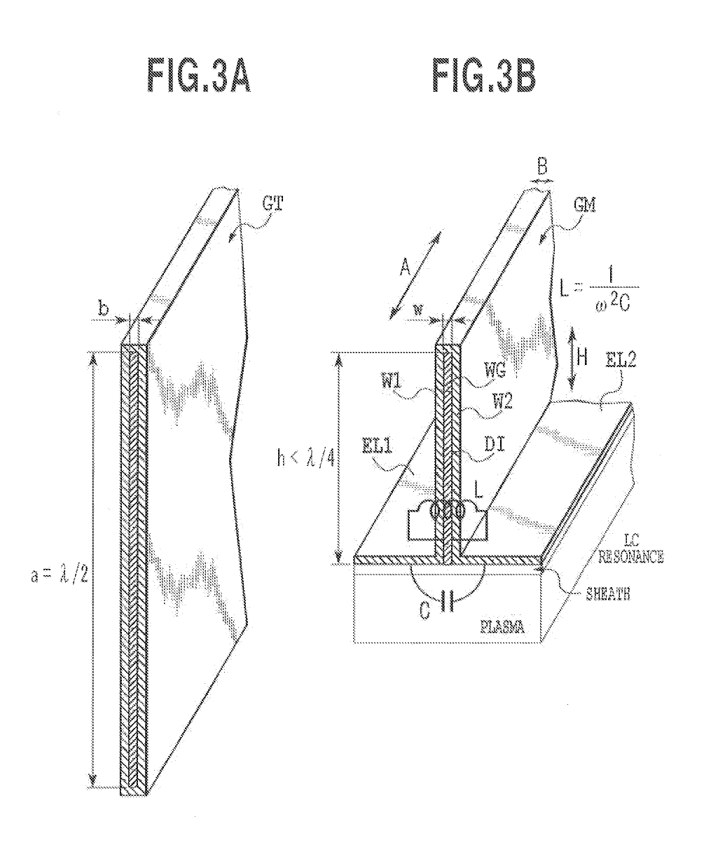

Here, resonance in a waveguide will be explained. First, as shown in FIG. 3A, an in-tube wavelength in a rectangular waveguide tube GT having a cross section with a long side length of a and a short side length of b is considered. An in-tube wavelength λg is expressed by formula (1).

$${λ}_{g} = \frac{λ}{\sqrt{{ɛ}_{r} {μ}_{r}} \sqrt{1 - λ / 2 a}} \qquad ( 1 )$$

Here, λ is a free space wavelength, εr is a relative permittivity in the waveguide tube, and μr is a relative permeability in the waveguide tube. According to formula (1), for εr=μr=1, if is found that the in-tube wavelength λg in the waveguide tube GT is always longer than the free space wavelength λ. For λ<2a, the in-tube wavelength λg becomes longer as the long side length a becomes smaller. For λ=2a, that is, when the long side length a is equal to ½ of the free space wavelength λ, the denominator becomes zero and the in-tube wavelength λg takes an infinite value. At this time, the waveguide tube GT becomes a cut-off state and phase velocity of an electromagnetic wave propagating in the waveguide tube GT takes an infinite value and group velocity becomes zero. Further, for λ>2a, the electromagnetic wave cannot propagate in the waveguide tube, while the electromagnetic wave can enter the waveguide tube to some extent. Note that, while generally this state is also called the cut-off state, here the state for λ=2a is called the cut-off state. For example, at a plasma excitation frequency of 60 MHz, a becomes 200 cm for a hollow waveguide tube and 81 cm for an alumina waveguide tube.

FIG. 3B shows a basic typo waveguide used for the plasma processing apparatus 10. A waveguide member GM defining this waveguide WG is formed of a conductive member, and includes side wall parts W1 and W2 which extend in the waveguide direction (longitudinal direction) A and face each other in the width direction B, and a first and a second electrode part EL1 and EL2 which extend in flange shapes in the lower end parts in the height direction H of the side wall parts W1 and W2. Further, a dielectric D1 in a plate shape is inserted in a gap formed between the side wall parts W1 and W2. This dielectric DI plays a role of preventing plasma excitation in the waveguide WG. A width w of the waveguide WG shown in FIG. 3B is set to a value equal to the snort side length b of the waveguide, and a height h is set to an optimum value smaller than λ/4 (a/2) so as to be electrically equivalent, to the waveguide tube GT in the cut-off state. In the waveguide WG, an LC resonance circuit is formed by L (inductance) and C (capacitance) to become the cut-off state, and thereby a supplied electromagnetic wave resonates. When the wavelength of a high frequency wave propagating in the waveguide WG in the waveguide direction A reaches an infinite value, a high-frequency electric field is formed uniformly in the longitudinal direction of the electrodes EL1 and EL2 and plasma is excited, having uniform density in the longitudinal direction. Here, if an impedance when viewed from the waveguide WG to the plasma side is assumed to have an infinite value, the waveguide WG can be assumed to be a transmission path which is formed by dividing a rectangular waveguide tube just in half in the long side direction. Therefore, when the height h of the waveguide WG is λ/4, the in-tube wavelength λg takes an infinite value. However, since actually the impedance when viewed from the waveguide WG to the plasma side is capacities, the height h of the waveguide WG causing the in-tube wavelength λg to take the infinite value is smaller than λ/4.

The plasma processing apparatus 10 includes a vacuum container 100 mounting a substrate G therein, and applies plasma processing to a glass substrate (hereinafter, called substrate G) therein. The vacuum container 100 has a rectangular cross section, is formed of metal such as aluminum alloy, and is earthed. An upper opening of the vacuum container 100 is covered by a ceiling part 105. The substrate G is mounted on a mounted stage 115. Note that the substrate G is an example of an abject to be processed, and the object to be processed is not limited to this case and may be a silicon wafer or the like.

On a floor part of the vacuum container 100, the mounting stage 115 is provided for mounting the substrate G. Above the mounting stage 115, plural (two) plasma generation mechanisms 200 are provided via a plasma formation space PS, The plasma generation mechanism 200 is fired to the ceiling part 105 of the vacuum container 100.

Each of the plasma generation mechanisms 200 includes two waveguide members 201A and 2018 which are formed of aluminum alloy and have the same size, a coaxial tube 225, and a dielectric plate 220 inserted in the waveguide WG formed between the two facing waveguide members 201A and 201B.

The waveguide members 201A and 201B include flat plate parts 201W which face each other with a predetermined gap for forming the waveguide WG and electrode parts 201EA and 201EB for electric field formation which are formed in flange shapes at the lower end parts of these flat plate parts 201W to excite plasma, respectively. The upper end parts of the waveguide members 201A and 201B are connected to a ceiling part 105 formed of conductive material and the upper end parts of the waveguide members 201A and 201B are electrically connected with each other.

The dielectric plate 220 is formed of dielectric such as aluminum oxide or quarts, and extends upward from the lower end of the waveguide WG to a midpoint or the waveguide WG. Since the upper part of the waveguide WG is short-circuited, an electric field is weaker on the upper side than on the lower side in the waveguide WG. Therefore, when the lower side of the waveguide WG where the electric field is strong is blocked up with the dielectric plate 220, the upper part of the waveguide WG may be hollow. Obviously, the waveguide WG may be filled with the dielectric plate 220 up to the upper part.

The coaxial tube 225 is connected to an approximately center position in the longitudinal direction A of the waveguide WG as shown in FIG. 2 and this position becomes a power supply position. An outer conductor 225b of the coaxial tube 225 is configured with a part of the waveguide member 201B, and an inner conductor 225a1 passes through the center part of the outer conductor 225b. The lower end part of the inner conductor 225a1 is electrically connected to an inner conductor 225a2 which is disposed perpendicularly to the inner conductor 225a1. The inner conductor 225a2 passes through a hole opened in the dielectric plate 220 and is electrically connected to the electrode part 201EA on the side of the waveguide member 201A.

The inner conductors 225a1 and 225a2 of the coaxial tube 225 die electrically connected to the one electrode part 201EA in the plasma generation mechanism 200, and the outer conductor 225b of the coaxial tube 225 is electrically connected to the other electrode part 201EB in the plasma generation mechanism 200. To the upper end of the coaxial tube 225, a high-frequency power source 250 is connected era a matching box 245. High-frequency power supplied from the high-frequency power source 250 propagates via the coaxial tube 225 from the center position in the longitudinal direction A toward both end parts of the waveguide WG.

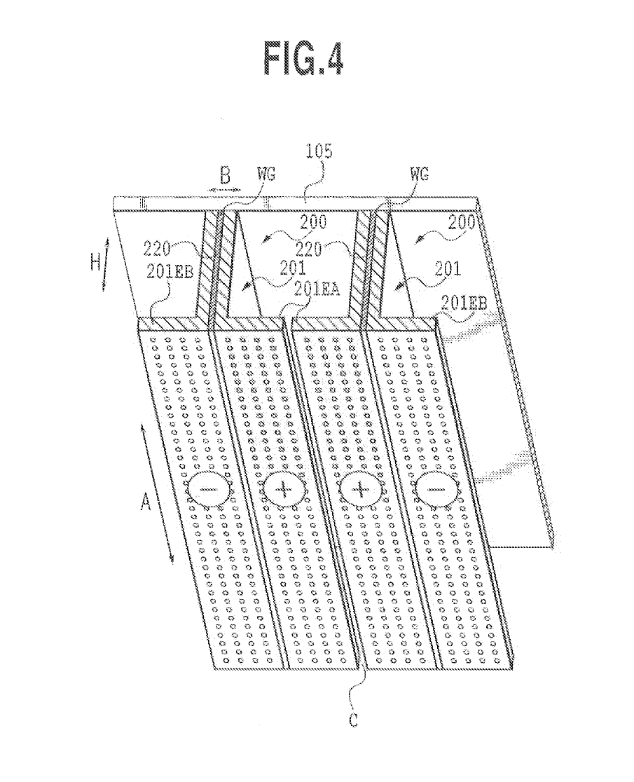

The inner conductor 225a2 passes through the dielectric plate 220. The inner conductors 225a2 provided in the respective adjacent, plasma generation mechanisms 200 pass through the respective dielectric plates 220 of the plasma generation mechanisms 200 in directions opposite to each other. Here, when the high frequency waves having the same amplitude and the same phase are supplied to the coaxial tubes 225 of the two plasma generation mechanisms 200, respectively, high frequency waves having the same amplitude and opposite phases cure applied to the electrode parts 201EA and 201EB in the two plasma generation mechanisms 200, respectively, as shown in FIG. 4. Here, in the present specification, high frequency wave means a wave in a frequency band of 10 MHz to 3,000 MHz and an example of an electromagnetic wave. Further, the coaxial tube 225 is an example of a transmission path supplying the high frequency wave, and a coaxial cable, a rectangular waveguide tube, or like may be used instead of the coaxial tube 225.

As shown in FIG. 1, for preventing discharge on the side faces of the electrode parts 201EA and 201EB and for preventing entry of plasma into the upper part, the side faces of the electrode parts 201EA and 201EB in the width direction B are covered with first dielectric covers 221. As shown in FIG. 2, for causing the end face of the waveguide WG in the longitudinal direction A to have an open state and also for preventing discharge on both of the side faces, both side faces of the flat plate parts 201W in the longitudinal direction A are covered with second dielectric covers 212.

While the lower face of the electrode parts 201EA and 201EB are formed so as to be approximately flush with the lower end face of the dielectric plate 220, the lower end face of the dielectric plate 220 may protrude or recede from the lower faces of the electrode parts 201EA and 201EB. The electrode parts 201EA and 201EB doable as shower plates. Specifically, concave parts are formed on the lower faces of the electrode parts 201BA and 201EB and electrode caps 270 for the shower plates are fit in these concave parts. Plural gas ejection holes are provided in the electrode cap 270, and gap having passed through a gas flow path is ejected from these gas ejection holes to the side of the substrate G. A gas nozzle made of an electrical insulator such as aluminum oxide is provided at the lower end of the gas flow path (refer to FIG. 1).

For performing uniform process, it is not sufficient only to realize the uniform plasma density. Gas pressure, source gas density, reaction-produced gas density, gas sojourn time, substrate temperature, and the like affect the process and therefore these factors are required to be uniform on the substrate G. In a typical plasma processing apparatus, a shower plate is provided at a part facing the substrate G and gas is supplied toward the substrate. The gas is configured to flow from the center part of the substrate G toward the outer perimeter part and to be exhausted from the periphery of the substrate. Naturally, pressure is higher in the center part than in the outer perimeter part on the substrate and the sojourn time is longer in the outer perimeter part than in the center part on the substrate, when the substrate size is increased, it is difficult to perform the uniform process because of the uniformity degradation of these pressure and sojourn time. For performing the uniform process also on a large area substrate, it is necessary to perform gas supply from directly above the substrate G and to perform exhaustion from directly above the substrate at the same time.

In the plasma processing apparatus 10, an exhaustion slit C is provided between the adjacent plasma generation mechanisms 200. That is, gas output from a gas supplier 290 is supplied to the processing chamber from the lower face of the plasma generation mechanism 200 through the gas flow path formed in the plasma generation mechanism 200, and exhausted so the upper direction from the exhaustion slit C provided directly above the substrate G. The gas having passed through the exhaustion slit C flows in a first exhaustion path 281 which is formed above the exhaustion slit C by the adjacent plasma generation mechanisms 200, and guided to a second exhaustion path 283 which is provided between the second dielectric cover 215 and the vacuum container 100. Furthers the gas flows downward in a third exhaustion path 285 which is provided on the side wail of the vacuum container 100 and exhausted by a vacuum pump (not shown in the drawing) which is provided below the third exhaustion path 285.

A coolant flow path 295a is formed on the ceiling part 105. Coolant output from a coolant supplier 295 flows in the coolant flow path 295a; and thereby heat flowing from the plasma is configured to be conducted to the side of the ceiling part 105 via the plasma generation mechanism 200.

In the plasma processing apparatus 10, an impedance variable circuit 380 is provided for electrically changing the effective height h of the waveguide WG. Other than the coaxial tube 225 which supplies the high frequency wave and is provided at the center part in the electrode longitudinal direction, two coaxial tubes 385 are provided in the vicinities of both ends in the electrode longitudinal direction for connecting the respective two impedance variable circuits 380. For not disturbing the gas flow in the first gas exhaustion path 281, an inner conductor 385a2 of the coaxial tube 385 is provided above the inner conductor 225a2 of the coaxial tube 225.

As a configuration example of the impedance variable circuit 380, there would be a configuration of using only a variable capacitor, a configuration of connecting a variable capacitor and a coil in parallel, a configuration of connecting a variable capacitor and a coil in series, and the like.

In the plasma processing apparatus 10, when the state becomes the cut-off state, the effective height of the waveguide WG is adjusted so as to cause reflection viewed from the coaxial tube 225 to have the smallest value. Further, preferably the effective height of the waveguide is adjusted also during the process. Therefore, in the plasma processing apparatus 10, a reflection meter 300 is attached between the matching box 245 and the coaxial tube 225 and a reflection state viewed from the coaxial tube 225 is configured to be monitored. A detection value by the reflection meter 300 is transmitted to a control section 305. The control section 305 provides an instruction of adjusting the impedance variable circuit 380 according to the detection value. Thereby, the effective height of the waveguide WG is adjusted and the reflection viewed from the coaxial, tube 225 is minimized. Note that, since a reflection coefficient can be suppressed to a very small value by the above control, the matching box 245 can be omitted from installation.

When high frequency waves having opposite phases are supplied to the two adjacent plasma generation mechanisms 200, as shown in FIG. 4, high frequency waves having the same phase are applied to the two adjacent electrode parts 201EA and 201EA, in this state, the high frequency electric field is not applied to the exhaustion slit C between the plasma generation mechanisms 200 and plasma is not generated in this part.

For not causing an electric field in the exhaustion slit C, the phases of the high frequency waves propagating in the respective adjacent plasma generation mechanisms 200 are shifted in 180 degrees from each other so as to cause high frequency electric fields to be applied in opposite directions.

As shown in FIG. 1, the inner conductor 225a2 of the coaxial tube disposed in the left-side plasma generation mechanism 200 and the inner conductor 225a2 of the coaxial tube disposed in the right-side plasma generation mechanism 200 are disposed in opposite directions. Thereby, the high frequency waves which are supplied from the high-frequency power source 250 having the same phase come to have opposite phases when transmitted to the waveguide WG via the coaxial tubes.

Note that, when the inner conductors 255a2 are disposed in the same direction, by applying high frequency waves having opposite phases to the respective adjacent pair of electrodes from the high-frequency power source 250, it is possible to cause high-frequency electric fields formed on the lower faces of all the electrode parts 201EA and 201EB in the plasma generation mechanisms 200 to have the same direction and to cause the high-frequency electric field in the exhaustion slit C to be zero.

### FIRST EMBODIMENT

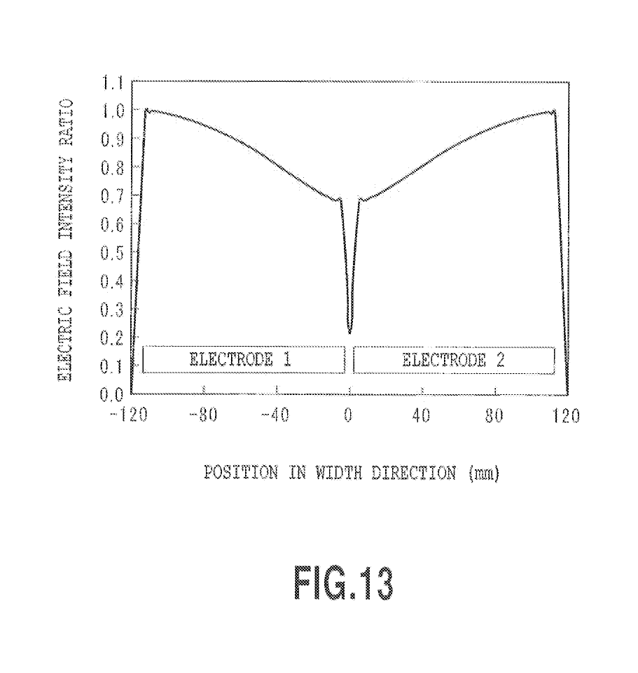

In the plasma processing apparatus 10 saving the above described configuration, by causing the waveguide WG to become the cut-off state, it is possible to excite uniform plasma on an electrode having a length larger than 2 m, for example. However, in a basic-type plasma processing apparatus as shown in FIG. 3B, the electric field strength in a sheath on the substrate surface in the width direction B of the waveguide WG has a distribution as shown in FIG. 13, for example. In FIG. 13, it is found that the electric filed strength is minimized in the center position of the first and second electrode parts EL1 and EL2 and maximized at both ends in the width direction B of the first and second electrode parts EL1 and EL2. When the electric filed strength is changed in the width direction B in this manner, plasma density uniformity in the width direction B is caused to be degraded. Further, in a structure in which the first and second electrode parts EL1 and EL2 are arranged in the width direction B while extending in the longitudinal direction A of the waveguide WG, when gas such as SiH₄ is supplied, sometimes plasma generation becomes unstable in the width direction B. Therefore, in the present embodiment, there will be explained a plasma generation mechanism in which the plasma density uniformity can be improved in the width direction B of the waveguide WG.

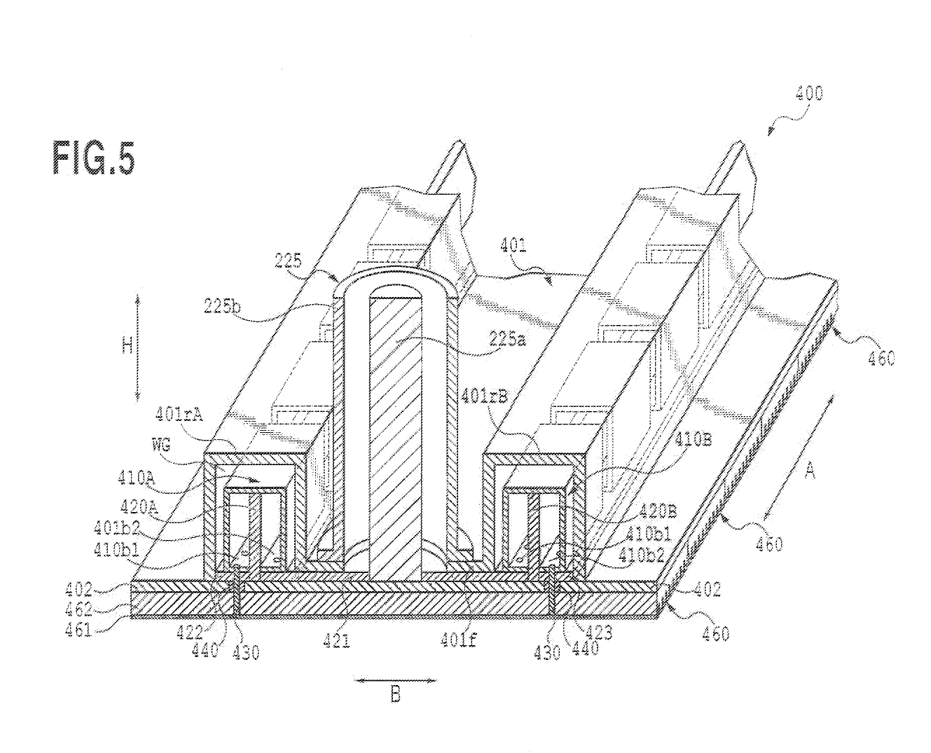

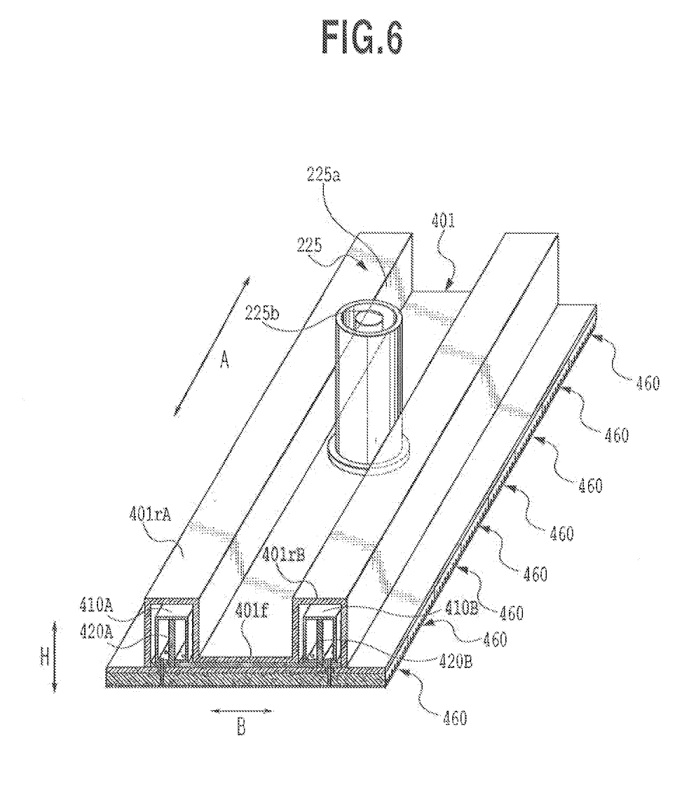

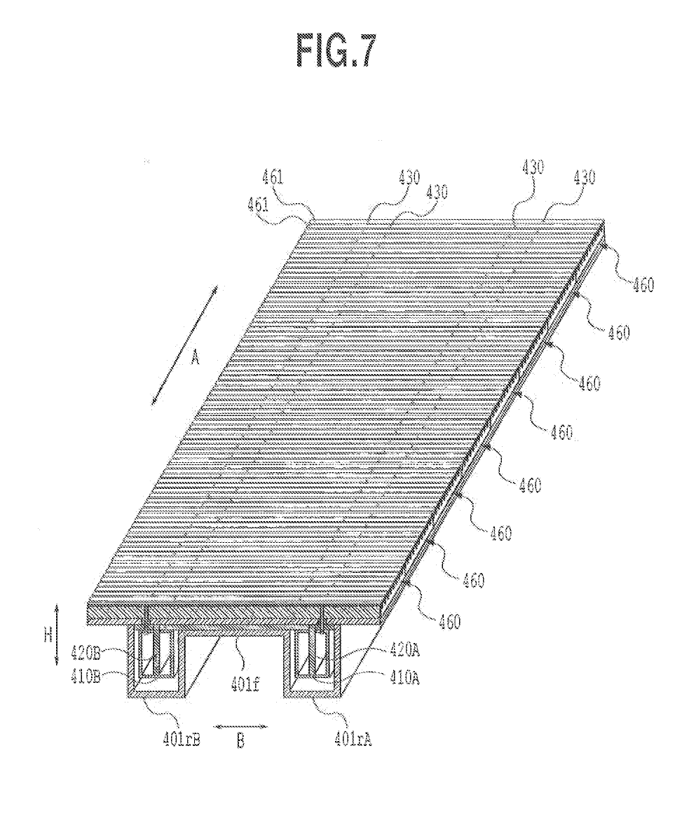

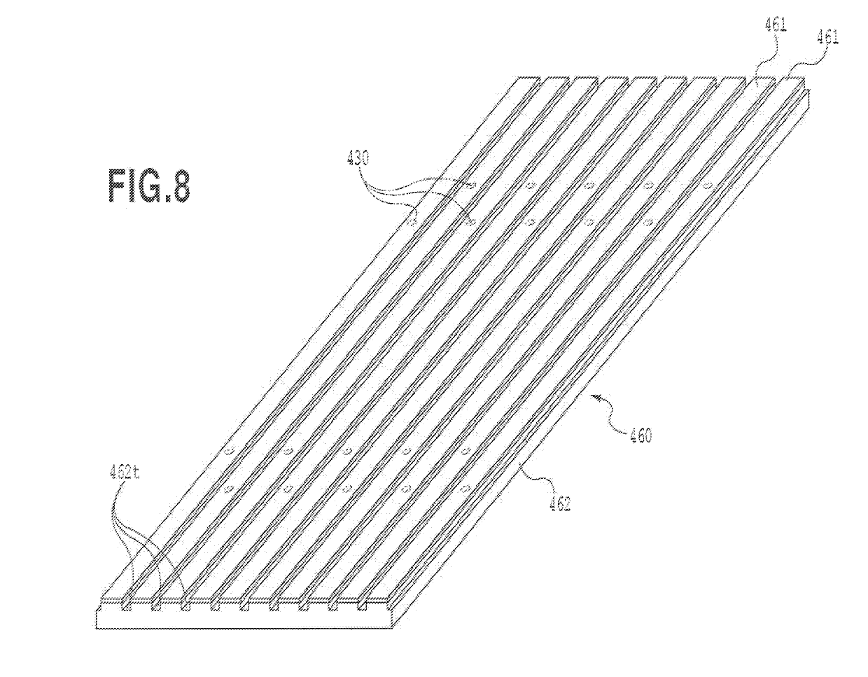

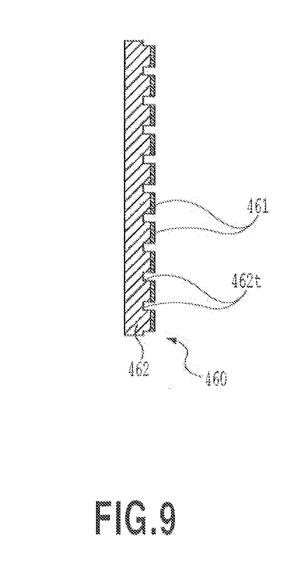

FIG. 5 is a perspective cross-sectional view of a plasma generation mechanism 400 according to the present embodiment. FIG. 6 is a perspective cross-sectional view showing an external appearance of the plasma generation mechanism of FIG. 5 when viewed from the coaxial tube side. FIG. 7 is a perspective cross-sectional view showing an external appearance of the plasma generation mechanism of FIG. 5 when viewed from the electrode side. FIG. 8 is a perspective view of an electrode unit. FIG. 9 is a cross-sectional view of the electrode unit. Here, the plasma generation mechanism 400 corresponds to each of the two plasma generation mechanisms 200 shown in FIG. 1 and FIG. 4. That is, the plasma processing apparatus according to the present embodiment replaces each of the two plasma generation mechanisms 200 shown in FIG. 1 and FIG. 4 with the plasma generation mechanism 400 shown in FIG. 5. In the plasma processing apparatus according to the present embodiment, there is provided an adjustment mechanism for causing the waveguide to be always in the cut-off state even when a load is changed, that is, the above described two impedance variable circuits 380 and two coaxial tubes 385 connecting the respective two impedance variable circuits 380.

The plasma generation mechanism 400 includes a first and a second waveguide member 401 and 402. The first waveguide member 401 is formed of conductive material such as aluminum alloy and has two raised parts 401rA and 401rB arranged in parallel and a flat part 401f extending between the two raised parts 401rA and 401rB. The second waveguide member 402 is formed in a plate shape with conductive material such as aluminum alloy, end the first waveguide member 401 is disposed on this second waveguide member 402. A waveguide WG having two raised parts is defined between the waveguide member 401 and the waveguide member 402. Dielectric plates 421 to 423 are provided on the second waveguide member 402, extending in the longitudinal direction A, and a part of the dielectric plate 421 contacts the lower race of the flat part 401f in the first waveguide member 401. The dielectric plates 421 to 423 are termed of dielectric material, such as fluorine resin. Note that, in the second waveguide member 402, a coolant flow path may be formed for keeping the electrode temperature constant.

In the two raised parts 401rA and 401rB or the waveguide WG, there are disposed plural first and second coil members 410A and 410B, respectively. Each or the first and second coil members 410A and 410B is formed of conductive material such as aluminum alloy and formed in a tubular shape which has a rectangular cross section in a direction crossing the longitudinal direction A. Each of the first and second coil members 410A and 410B is an approximately one-turn coil and is disposed in the waveguide WG so as to generate a voltage by electromagnetic induction due to a magnetic field in the waveguide WG. A first and a second end part 410b1 and 410b2 of the first coil member 410a in the turn direction are disposed on the dielectric plates 421 and 422 and face each other having a predetermined gap. A first and a second end part 410b1 and 410b2 of the second ceil member 410B in the turn direction are disposed on the respective dielectric plates 423 and 421 and face each other with a predetermined gap.

In the first raised cart 401rA of the first waveguide member 401, a first dielectric plate 420A is provided so as to pass through the plural first coil members 410A. The lower end part of the first dielectric plate 420A is inserted between the first and second end parts 410b1 and 410b2 facing each other in the first coil member 410A, and also inserted between the dielectric plats 421 and the dielectric plate 422. In the second raised part 401rB of the first waveguide member 401, a second dielectric plate 420rB is provided so as to pass through the plural second, coil members 410B. The lower end part of the second dielectric plate 420B is inserted between the first and second end parts 410b1 and 410b2 facing each other in the second coil member 410B, and also inserted between the dielectric plate 421 and the dielectric plate 423. The first and second dielectric plates 420A and 420B are made of dielectric material such as fluorine resin.

A coaxial tube 225 is, as shown in FIG. 5 and FIG. 6, electrically connected to the first and second waveguide members 401 and 402 at an approximately center position in the longitudinal direction A of the waveguide WG, and supplies electromagnetic energy into the waveguide WG. Specifically, the coaxial, tube 225 is provided between the first and second raised parts and disposed along the height direction of the waveguide WG. Then, the lower end part of an inner conductor 225a passes through the dielectric plate 421 in the height direction H and is electrically connected to the second waveguide member 402 having a plate shape. The lower end part of an outer conductor 225a is electrically connected to the flat part 401f of the first waveguide member 402.

On the lower face of the second waveguide member 402, plural (eight) electrode units 460 are arranged in the longitudinal direction A. The electrode unit 460 includes a dielectric plate 462 formed in a rectangular shape and plural electrodes 461 formed on the surface of this dielectric plate 462. The dielectric plate 462 is formed of dielectric material such as aluminum oxide and the upper face thereof contacts the lower face of the second waveguide member 402. The plural electrodes 461 are configured with metal films which are electroplated on the surface of the dielectric plate 462, and the plural electrodes 461 have predetermined widths, and extend in the width direction B of the waveguide WG and also are arranged in a predetermined pitch in the longitudinal direction A of the waveguide WG. The arrangement pitch is approximately 10 mm, for example.

On the dielectric plate 402, there are formed plural Grooves 462t extending along the two adjacent electrodes 461 and having a predetermined depth, between the two neighboring electrodes 461 on a face where the electrodes 461 are formed. The groove 462t is provided for reducing parasitic capacitance between the two adjacent electrodes 461. That is, by providing the groove 462i, it is possible to reduce electromagnet is energy loss and to improve efficiency.

The dielectric plate 462 is used as a shower plate. In this cast, the above described gas ejection hole is provided in the groove 462t. That is, an exit of the gas ejection hole passing through the dielectric plate is formed in the groove 402t. Since the electric field is weaker in the groove 402t than on the surface of the electrode 461, by providing the gas ejection hole in the groove 462t, it is possible to suppress discharge in the gas ejection hole.

The plural electrodes 461 are electrically connected to the first and second coil members 410A and 410B with connection pins 430 which are formed of conductive material such as aluminum alloy. Specifically, as shown in FIG. 5 and FIG. 6, the connection pin 430 connected to the first end part 410b1 of the first coil member 410A passes through the dielectric plate 422, the second waveguide member 402, and the dielectric plate 462, and is electrically connected to the corresponding electrode 461 among the plural electrodes 461. The connection pin 430 connected to the second end part 410b2 of the second coil member 410B passes through the dielectric plate 423, the second waveguide member 402, and the dielectric plate 462 and is connected to the corresponding electric 461 among the plural electrodes 461. The connection pin 430 connected to the first end part 410b1 of the first coil member 410A and the connection pin 430 connected to the second end part 410b2 of the second coil member 410b are connected to the common electrode 461.

Similarly, the connection pin 430 connected to the second end part 410b2 of the first coil member 410A passes through the dielectric plate 421, the second waveguide member 402, and the dielectric plate 462 and is electrically connected to the corresponding electrode 461 among the plural electrodes 461. The connection pin 430 connected to the first end part 410b1 of the second coil member 410B passes through the dielectric plate 421, the second waveguide member 402, and the dielectric plate 462, and is connected to the corresponding electrode 461 among the plural electrodes 461. The connection pin 420 connected to the second end part 410b2 of the first coil member 410A and the connection pin 430 connected to the first end part 41011 of the second coil member 410B are connected to the common electrode 461. Here, the connection pin 430 and the second waveguide member 402 are electrically separated by a dielectric 440.

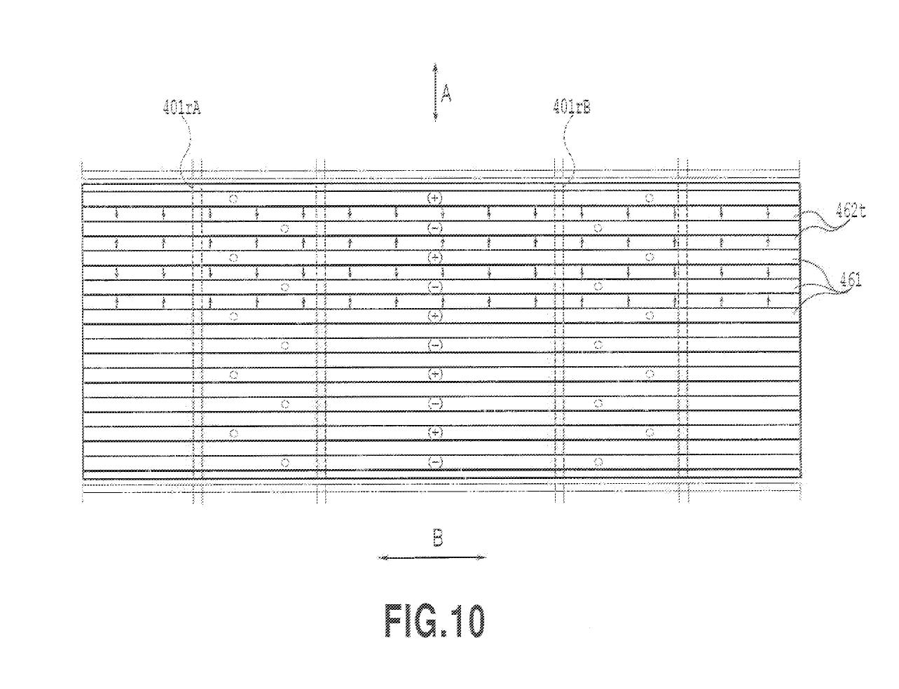

In the plasma generation mechanism 400, as shown in FIG. 10, when electromagnetic energy is supplied from the coaxial tube 225 to the plural electrodes 461 through the waveguide WG, high, frequency wares having the same amplitude and opposite phases are applied to the two electrodes 461 adjacent each other in the longitudinal direction A of the waveguide WG. By these high frequency waves, as shown by the arrow in FIG. 10, an electric field is formed direct user from one to the other of the two adjacent electrodes 461. The strength of this electric field is approximately uniform in the longitudinal direction of the electrode 461, that is, in the width direction or the waveguide WG. As a result, it is possible to improve the plasma density uniformity in the longitudinal direction of the electrode 461, that is, in the width direction of the waveguide

In the present embodiment, the plural first and second coil members 410A or 410B are disposed along the longitudinal direction A. If the plural coil members 410A or 410B are united into one, sometimes there is generated a mode propagating within the coil members 410A or 410B in the longitudinal direction A and the plasma density uniformity in the longitudinal direction A is degraded depending on the condition. In the present embodiment, by dividing the coil member intra plural parts, it is possible to suppress the generation of such a mode. Note that, depending on the condition, each of the coil members 410A and 410B may not be divided into plural parts in the longitudinal direction A. The forms of the coil members 410A and 410B are not limited to the forms of the present embodiment. For example, for the cross-sectional shape, various shapes such as a circular shape and an ellipsoidal shape may be employed other than the rectangular shape. Further, except the approximately one-turn coil, a half-turn coil or a multi-turn coil may be used, for example.

### Variation

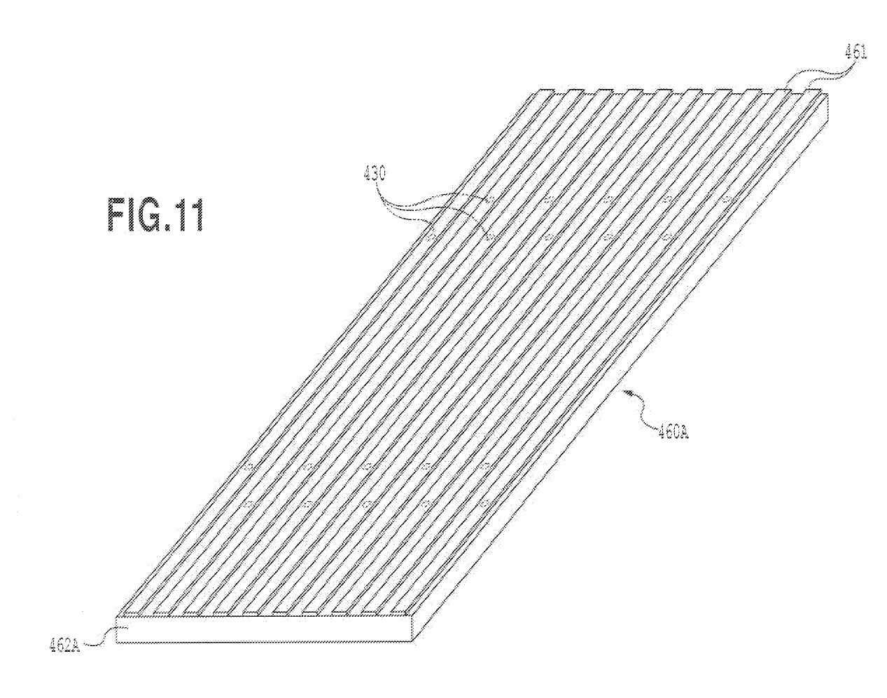

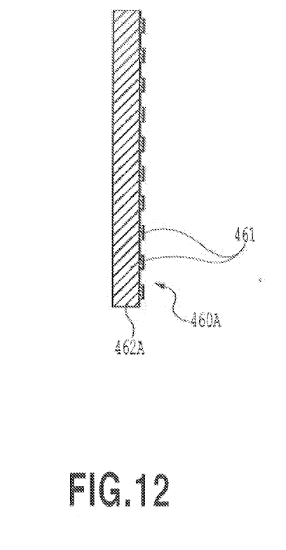

In the first embodiment, the case of forming the plural grooves 462t on the dielectric plate 462 has been explained, it is also possible to use the dielectric plate 462 on varied the plural grooves 462t are not formed as shown in FIG. 11 and FIG. 12, for example.

The electrode is formed of the electroplated metal film on the dielectric plate 462, not limited to this case, the electrode 461 and the dielectric plate 462 can be formed separately. Further, the electrode 461 can be formed of a metal member instead of the metal film.

In the first embodiment, the case of keeping the waveguide WG in the cut-off state has been explained, the electrode unit of the present invention can be applied to a waveguide in a state except the cut-off state.

In the first embodiment, the waveguide is a so-called double-ridge type, not limited to this case, the present invention can be applied to various types of waveguide.

In the first embodiment, the dielectric plate 462 doubles as the shower plate, the dielectric plate 462 may not be used as the shower plate.

In the first embodiment, the power supply position is the center position in the longitudinal direction of the waveguide, not limited to this case, the power supply position can be changed as needed. Further, the power supply position can be provided not only at one position but also at plural positions in the longitudinal direction of the waveguide.

The embodiment eat the present invention has been explained above in detail with reference to the attached drawings, the present invention is not limited to such an example. Obviously, those having usual knowledge in the technical field to which the present invention belongs can conceive various kinds of variation and modification within the range of the technical idea which is described in claims, and it is to be understood that also these variations and modifications naturally belong to the technical scope of the present invention.

### REFERENCE SIGNS LIST

225 Coaxial tube
400 Plasma generation mechanism
410A, 410B Coil member
401, 402 Waveguide member
WG Waveguide
460 Electrode unit
461 Electrode
462 Dielectric plate
PS Plasma formation space

1. A plasma processing apparatus, comprising:
a waveguide member defining a wave guide;
a transmission path supplying electromagnetic energy from a predetermined power supply position in a longitudinal direction of the waveguide into the waveguide, the longitudinal direction being a waveguide direction; and
a plurality of electrodes for electric field formation disposed so as to face a plasma formation space and receiving the electromagnetic energy supplied through the waveguide, wherein
the plurality of electrodes are arranged in the longitudinal direction of the waveguide, and
each of the plurality of electrodes extends in a width direction of the waveguide, the width direction being perpendicular to the longitudinal direction of the guide wave and a width direction, the width direction being parallel to an electromagnetic wavefront.

2. The plasma processing apparatus according to claim 1, wherein
each of the plurality of electrodes is formed of a metal film electroplated on a surface of a dielectric plate.

3. The plasma processing apparatus according to claim 2, wherein
the dielectric plate includes a plurality of grooves, each of the grooves being formed between two adjacent electrodes of the plurality of electrodes and extending along the two adjacent electrodes.

4. The plasma processing apparatus according to claim 2, wherein
the dielectric plate is in contact with a part of the waveguide member.

5. The plasma processing apparatus according to claim 2, wherein
the dielectric plate doubles as a shower plate.

6. The plasma processing apparatus according to claim 1, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

7. The plasma processing apparatus according to claim 6, wherein
the transmission path includes a coaxial tube, and
the coaxial tube extends between the first and second raised parts of the waveguide in a height direction of the first and second raised parts and is connected to the first and second waveguide members, the height direction being perpendicular to the longitudinal direction and width direction of the wave guide.

8. The plasma processing apparatus according to claim 1, wherein
dimensions of the waveguide in the width direction and in a height direction perpendicular to the longitudinal and width directions of the waveguide are defined so as to cause a high frequency wave to resonate, the high frequency wave being supplied from the transmission path and having a predetermined plasma excitation frequency.

9. A plasma processing method, comprising the steps of:
disposing an object to be processed at a position facing a plasma formation space in a container provided therein with a plasma generation mechanism, the mechanism comprising:
a waveguide member defining a wave guide;
a transmission path supplying electromagnetic energy from a predetermined power supply position in a longitudinal direction of the waveguide into the waveguide, the longitudinal direction being a waveguide direction; and
a plurality of electrodes for electric field formation, to which the electromagnetic energy is supplied through the waveguide and which is disposed so as to face a plasma formation space, wherein the plurality of electrodes is arranged along the longitudinal direction of the waveguide, and each of the plurality of electrodes extends in a width direction of the waveguide, the width direction being perpendicular to the longitudinal direction of the guide wave and a width direction, the width direction being parallel to an electromagnetic wavefront; and
applying plasma processing to the object to be processed with plasma excited by the plasma generation mechanism.

10. The plasma processing apparatus according to claim 3, wherein
the dielectric plate is in contact with a part of the waveguide member.

11. The plasma processing apparatus according to claim 3, wherein
the dielectric plate doubles as a shower plate.

12. The plasma processing apparatus according to claim 4, wherein
the dielectric plate doubles as a shower plate.

13. The plasma processing apparatus according to claim 10, wherein
the dielectric plate doubles as a shower plate.

14. The plasma processing apparatus according to claim 2, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

15. The plasma processing apparatus according to claim 3, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

16. The plasma processing apparatus according to claim 4, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

17. The plasma processing apparatus according to claim 10, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

18. The plasma processing apparatus according to claim 5, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

19. The plasma processing apparatus according to claim 11, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.

20. The plasma processing apparatus according to claim 12, wherein
the waveguide member includes a first waveguide member formed so as to define a waveguide which has a first and a second raised part juxtaposed to each other and a second waveguide member defining the waveguide in cooperation with the first waveguide member, and
the waveguide member further includes a first and a second coil member which are disposed in the first and second raised parts respectively so as to generate a voltage by electromagnetic induction due to a magnetic field and also electrically connected to the plurality of electrodes.
